(19) United States
(12) Patent Application Publication
(10) Pub. No.: US 2007/0099434 A1
(43) Pub. Date: May 3, 2007

(54) Method of forming oxide film of semiconductor device

(75) Inventor: Cha Deok Dong, Icheon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/480,325

(22) Filed: Jun. 30, 2006

(30) Foreign Application Priority Data
Nov. 1, 2005 (KR) 10-2005-104012

(51) Int. Cl. H01L 21/31; H01L 21/469

(52) U.S. Cl. 438/769; 438/770; 438/780

(57) ABSTRACT

An oxide film is formed by a radical oxidization process and nitrogen is introduced into the oxide film by an annealing process using NO gas. The nitrogen gathered at the interface of the oxide film and a semiconductor substrate is re-distributed by an annealing process using a mixed gas including O₂ and N₂.

### BACKGROUND

The present invention relates to a semiconductor device, and more particularly to a method of forming an oxide film in a semiconductor device using a radical oxidization process.

In the manufacturing of semiconductor devices, the formation of an oxide film plays an important role. In recent years a process called radical oxidation has been used to form tunnel oxide film in flash memory devices. The radical oxidization process is a method of depositing the oxide film by forming radices, such as H₂ and O₂. The method is comparable to a method using H₂O vapor in the existing oxidization process.

To improve the properties of the tunnel oxide film formed by the radical oxidization process, nitrogen is absorbed into the tunnel oxide film by an annealing process using N₂O gas. In this case, since the trap density can be reduced and the stress-induced leakage current (SILC) and capacitance-voltage (C-V) characteristics can be improved, cycling and retention characteristics can be improved.

If in-situ annealing using N₂O gas is performed in the same equipment after the tunnel oxide film is formed by the radical oxidization process, not enough nitrogen is absorbed within the tunnel oxide film; unlike N₂O ex-situ annealing, which uses a furnace after the tunnel oxide film is formed by the radical oxidization process. This is shown in FIG. 1. It can be seen from the graph that in the case where N₂O ex-situ annealing is used (A10), about 2.88 atomic % of nitrogen is absorbed at the interface of the tunnel oxide film and the semiconductor substrate. However, when N₂O in-situ annealing is used (A20), about 0.91 atomic % of nitrogen is absorbed at the interface of the tunnel oxide film and the semiconductor substrate.

The radical oxidization equipment used in the in-situ annealing performs the process while maintaining a low pressure, unlike the furnace, and also has a slightly different difference in the tube structure, pipe, and so on. To try to match the nitrogen concentration in the ex-situ process, the in-situ process can be adjusted (i.e., increase pressure, flow rate and anneal time), but even in this case, only about 80% of the desired nitrogen concentration can be obtained.

As a solution to the problem, an attempt has been made to introduce nitrogen into the oxide film by annealing using NO gas instead of N₂O gas. NO gas has a better reactivity compared to N₂O gas. In NO annealing, however, the properties of the tunnel oxide film are degraded due to variations in the nitrogen profile and gas within the oxide film. As a result, this method is not suitable.

FIG. 2 shows the nitrogen concentration profile for N₂O ex-situ annealing in an oxidation furnace (B10) vs. NO in-situ annealing in the radical oxidation apparatus (B20).

From FIG. 2, it can be seen that the nitrogen concentration profiles are similar, except the peak of the nitrogen concentration is higher and the width of the curve is narrower in the case of NO annealing. In a tunnel oxide film having such a nitrogen concentration profile (B20), the trap density increases and the flat-band voltage (Vfb) shift becomes profound, resulting in degraded properties compared to using N₂O annealing. This is because nitrogen cohered at the interface degrades the properties of the tunnel oxide film.

### SUMMARY OF THE INVENTION

An embodiment of the present invention provides a method of forming an oxide film in a semiconductor device, which can prevent the coherence of nitrogen and its negative effects using a radical oxidization process and NO annealing.

In an embodiment of the present invention, nitrogen at the interface of the oxide film and the semiconductor substrate is redistributed during the radical oxidization process and NO in-situ annealing using a mixed gas of O₂ and N₂ are performed. Accordingly, the trap density can be reduced and the characteristics of the tunnel oxide film can be improved.

According to an aspect of the present invention, there is provided a method of forming an oxide film of a semiconductor device including the steps of; performing a radical oxidization process to form an oxide film on a semiconductor substrate in which predetermined structures are formed; introducing nitrogen into the oxide film by a primary anneal process using a gas containing nitrogen; and re-distributing the nitrogen within the oxide film by a secondary anneal process. The radical oxidization process, the primary anneal process, and the secondary anneal process may be performed in-situ on the same equipment.

According to another aspect of the present invention, there is provided a method of forming an oxide film of a semiconductor device including the steps of; loading a boat onto a radical oxidizer, where a semiconductor substrate is charged; then stabilizing the radical oxidizer; placing a vacuum in the radical oxidizer and then ramping up to a predetermined temperature; performing a radical oxidization process to form an oxide film on the semiconductor substrate; placing a vacuum in the radical oxidizer to remove any remaining gases; then performing backfill to normalize the pressure in the radical oxidizer; performing a primary anneal process using NO gas to introduce nitrogen into the oxide film; performing a secondary anneal process using a mixed gas of O₂ and N₂, to re-distributing the nitrogen within the oxide film; and purging remaining gas within the radical oxidization apparatus, ramping down the temperature, and unloading the boat.

In another embodiment, a method of forming an oxide film of a semiconductor device includes performing a radical oxidization process to form an oxide film on a semiconductor substrate. Nitrogen atoms are introduced into the oxide film using a first anneal process employing a gas containing nitrogen. The nitrogen atoms gathered at an interface between the oxide film and the semiconductor substrate are re-distributed using a second anneal process. The radical oxidization process, the first anneal process, and the second anneal process are performed in-situ in the same equipment.

In another embodiment, a method of forming an oxide film of a semiconductor device includes providing a semiconductor substrate into a radical oxidization apparatus; stabilizing the radical oxidization apparatus after the substrate has been provided within the radical oxidization apparatus; performing a radical oxidization process to form an oxide film on the semiconductor substrate; removing a gas remaining within the radical oxidization apparatus after the radical oxidization process; performing a first anneal process employing NO gas to introduce nitrogen atoms into the oxide film, the first anneal process resulting in a plurality of nitrogen atoms to gather at an interface between the oxide film and the substrate; performing a second anneal process employing a mixed gas including O₂ and N₂ to re-distribute the nitrogen atoms gathered at the interface; and removing the substrate from the radical oxidization apparatus after performing the second anneal process.

In yet another embodiment, the radical oxidization process is performed using O₂ and H₂ gases at a temperature of 750 to 950° C. and a pressure of no more than 3 torr. The second anneal process is performed for about 5 to 60 minutes employing the mixed gas including O₂ and N₂. A total flow rate of the mixed gas is about 1 to 20 slm. A ratio of O₂ and N₂ is set to be 1:20 to 5:5. The oxide film has a nitrogen concentration of 1 to 5 atomic %.

### BRIEF DESCRIPTION OF THE DRAWINGS

A more complete appreciation of the invention, and many of the attendant advantages thereof will be readily apparent and become better understood with reference to the following detailed description when considered in conjunction with the accompanying drawings in which like reference symbols indicate the same or similar components, wherein:

FIG. 1 is a graph comparing the nitrogen concentration between the ex-situ furnace N₂O anneal process and the in-situ N₂O anneal process after the radical oxidization process;

FIG. 2 is a graph comparing the nitrogen concentration when N₂O annealing is performed in the oxidization furnace and when in-situ NO annealing is performed in the radical oxidization apparatus;

FIG. 3 is a process recipe illustrating a method of forming an oxide film of a semiconductor device according to an embodiment of the present invention; and

FIG. 4 is a graph comparing the nitrogen concentration when NO annealing is performed in-situ in the radical oxidization apparatus and when NO annealing and annealing using a mixed gas of O₂ and N₂ are performed in-situ in the radical oxidization apparatus.

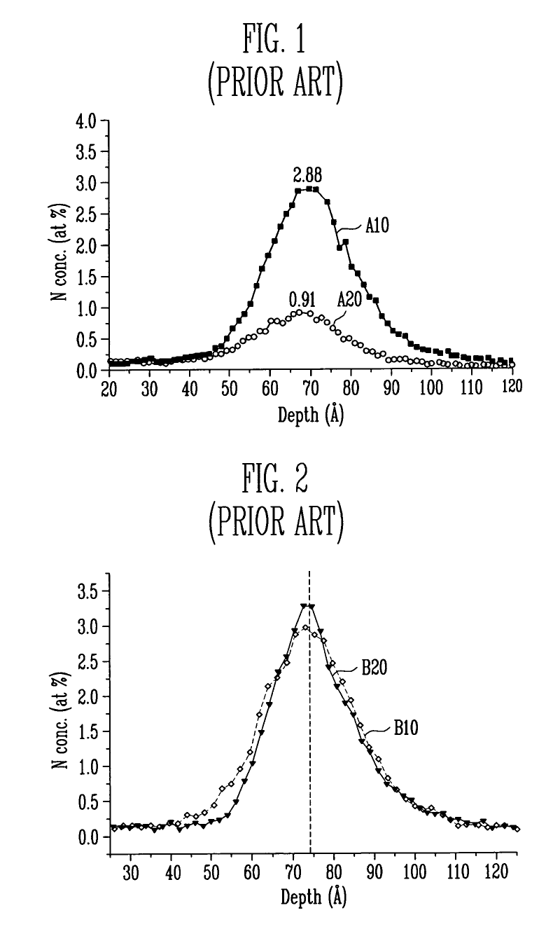

### DETAILED DESCRIPTION OF EMBODIMENTS

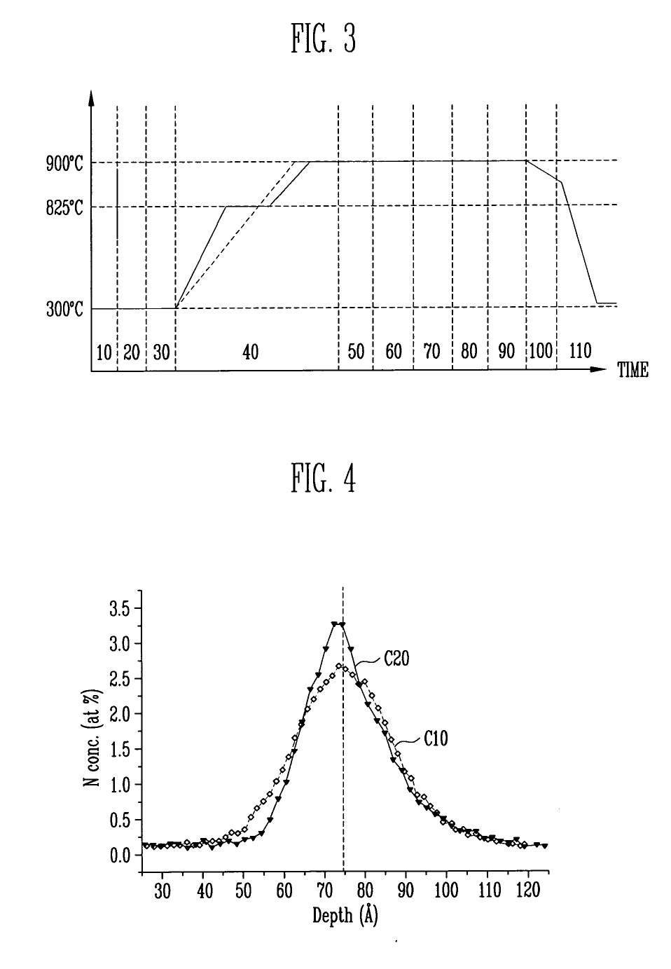

Referring to FIG. 3,a semiconductor substrate in which predetermined structures (e.g., wells) are already formed is loaded onto a boat. The boat is then loaded into the radical oxidization apparatus (step 10). Upon loading, a small amount of oxygen (e.g., ˜1%) is introduced and the radical oxidization apparatus is maintained at a temperature of 300 to 600° C.

After the boat is loaded, the radical oxidization apparatus is stabilized for a predetermined time (step 20). At this time, the boat is rotated in order to improve the thickness uniformity. The boat is rotated at a rate of about 1 to 2 rpm. Furthermore, when the boat is loaded, the apparatus is kept in an ozone environment in order to remove organic contaminants adsorbed on the top surface of the semiconductor substrate. The ozone is kept to a density of 100 to 200 g/N m³ (grams per normal cubic meter).

The vacuum in the radical oxidization apparatus is maintained for a time period (step 30). This is for the radical oxidization process, which is performed at a low pressure.

The temperature of the radical oxidization apparatus is ramped up to the radical oxidization temperature (step 40). In the case of an apparatus that allows fast ramp-up, the temperature can be ramped up to the rate of 50 to 100° C./min. For the high temperature case, the temperature is ramped up in two steps and ramp-up pressure is kept at 50 to 760 Torr (atmospheric pressure) in order to prevent scratches due to slip caused by the difference in the coefficient of thermal expansion between the boat and wafer. These small scratches can cause defects on the back side of the semiconductor.

A radical oxidization process is performed in order to form an oxide film with a desired thickness (step 50). The semiconductor substrate is oxidized by forming radicals using O₂ and H₂ at a constant pressure. For example, the radical oxidization process may be performed at a temperature of 750 to 950° C. and a pressure of 0.1 to 3 Torr (a pressure less than 0.1 Torr is also acceptable) using O₂ and H₂ gases. The ratio of O₂ to H₂ may have ratio of 9:1 to 6:4, wherein the content of H₂ is about 10 to 40%. The combined rate of oxygen and hydrogen introduced may be set to about 1 to 10 slm.

After the radical oxidization process is performed, the apparatus is kept in vacuum is maintained to remove any remaining gas (step 60).

The pressure is normalized using a backfill (step 70). Normal pressure is used in the NO annealing process in order to increase the partial pressure of the NO gas.

After the NO annealing, nitrogen is introduced into the interface between the oxide film and the semiconductor substrate (step 80). Annealing using NO gas may be performed using a mixed gas of NO and N₂ at a temperature of 750 to 1000° C. To increase the partial pressure of NO gas, annealing may be performed at atmospheric pressure (750 to 770 Torr) or a pressure of 10 to 740 Torr for about 5 to 60 minutes.

Annealing using a mixed gas of O₂ and N₂ is performed (step 90). The semiconductor substrate is weakly oxidized. After NO annealing is performed, nitrogen, which is cohered at the interface between the oxide film and the semiconductor substrate is redistributed over the oxide film.

The anneal process using a mixed gas of O₂ and N₂ is performed at atmospheric pressure of 750 to 770 Torr for 5 to 60 minutes. The ratio of O₂ to N₂ is set to about 1:20 to 5:5; and a mixed gas flow rate of is set to about 1 to 20 slm. These settings enable easier control of oxide thickness and helps prevent over oxidization of the semiconductor substrate.

A purge process is repeated several times to remove the gas remaining inside the apparatus (step 100). Removing any remaining gas will ensure that the thickness of the tunnel oxide film will not increase.

Thereafter, the boat is unloaded when the temperature of the apparatus is ramped down to a safe level (step 110).

The oxide film formed by the radical oxidization process and the annealing process using the mixed gas of O₂ and N₂ is set to have a nitrogen concentration of 1.0 to 5.0 atomic %.

As can be seen from FIG. 4, after performing additional annealing using a mixed gas of O₂ and N₂, the peak is lowered and an overall width of the curve is increased (C10), which is almost the same profile as that when N₂O annealing is performed in the furnace. This means the nitrogen cohered at the interface has been re-distributed and the problem with NO annealing of the tunnel oxide film can be solved accordingly.

The radical oxidization process, as described above, can also be applied to a thin dielectric film having an ONO structure (i.e., 15˜20 Å) since it is suitable for forming thin oxide films. Since the radical oxide film has better properties than the thermal oxide film, the dielectric film will improve program and erase operations in a memory cell.

Using the processes in the present embodiments, the trap density can be lowered and the nitrogen concentration profile can be lowered, e.g., to a level that is 1 equivalent to when N₂O annealing is performed in a furnace.

Furthermore, the oxidization process, the NO annealing process, and the annealing process employing the mixed gas of O₂ and N₂ can be performed in-situ in the radical oxidization apparatus. Accordingly, cost can be reduced by performing two processes in the same equipment.

Therefore, cycling and retention characteristics can be improved by improving the flat-band voltage shift and the charge trap density.

While the invention has been described in connection with what is presently considered to be specific embodiments, it is to be understood that the invention is not limited to the disclosed embodiments, but is intended to cover various modifications and equivalent arrangements included within the spirit and scope of the appended claims.

What is claimed is:

1. A method of forming an oxide film of a semiconductor device, the method comprising:
performing a radical oxidization process to form an oxide film on a semiconductor substrate;
introducing nitrogen atoms into the oxide film using a first anneal process employing a gas containing nitrogen; and
re-distributing the nitrogen atoms gathered at an interface between the oxide film and the semiconductor substrate using a second anneal process.

2. The method as set forth in claim 1, wherein the radical oxidization process, the first anneal process, and the second anneal process are performed in-situ in the same equipment.

3. The method as set forth in claim 1, wherein the radical oxidization process is performed using O₂ and H₂ gases at a temperature of 750 to 950° C. and a pressure of no more than 3 torr.

4. The method of claim 3, wherein the radical oxidization process is performed at the pressure between 0.1 to 3 Torr.

5. The method as set forth in claim 3, wherein the O₂ and H₂ have the ratio of 9:1 to 6:4 and a total flow rate of 1 to 10 slm.

6. The method as set forth in claim 1, wherein the first anneal process is performed using NO gas at a temperature of 750 to 1000° C. for about 5 to 60 minutes.

7. The method as set forth in claim 1, wherein the first anneal process is performed using a mixed gas of NO and N₂ at a pressure of 10 to 750 torr for about 5 to 60 minutes.

8. The method as set forth in claim 1, wherein the second anneal process is performed using a mixed gas of O₂ and N₂ at an atmospheric pressure for about 5 to 60 minutes.

9. The method as set forth in claim 8, wherein in the mixed gas of O₂ and N₂, O₂ and N₂ have the ratio of 1:20 to 5:5 and are introduced so that a total flow rate is about 1 to 20 slm.

10. The method as set forth in claim 1, wherein the oxide film formed by the radical oxidization process, the first anneal process, and the second anneal process has a nitrogen concentration of 1 to 5 atomic %.

11. A method of forming an oxide film of a semiconductor device, the method comprising:
providing a semiconductor substrate into a radical oxidization apparatus;
stabilizing the radical oxidization apparatus after the substrate has been provided within the radical oxidization apparatus;
performing a radical oxidization process to form an oxide film on the semiconductor substrate;
removing a gas remaining within the radical oxidization apparatus after the radical oxidization process;
performing a first anneal process employing NO gas to introduce nitrogen atoms into the oxide film, the first anneal process resulting in a plurality of nitrogen atoms to gather at an interface between the oxide film and the substrate;
performing a second anneal process employing a mixed gas including O₂ and N₂ to re-distribute the nitrogen atoms gathered at the interface; and
removing the substrate from the radical oxidization apparatus after performing the second anneal process.

12. The method of claim 11, further comprising:
depressurizing the radical oxidization apparatus to a vacuum atmosphere once the substrate is provided within the radical oxidization apparatus;
ramping up a temperature of the radical oxidization apparatus to a first predetermined temperature after the depressurizing step, the ramp-up step being performed prior to the performing-a-radical-oxidization-process step;
removing gases remaining within the radical oxidization apparatus after the second anneal process; and
ramping down the temperature of the radical oxidization apparatus to a second predetermined temperature.

13. The method as set forth in claim 11, wherein the radical oxidization apparatus is kept to a temperature of 300 to 600° C. while the substrate is being provided within the radial oxidization apparatus.

14. The method as set forth in claim 11, wherein the substrate is provided within the radical oxidization apparatus via a boat, wherein the boat is rotated at a rate of 1 to 2 rpm during the stabilizing step.

15. The method as set forth in claim 11, wherein the radical oxidization apparatus is provided with an ozone environment while the radical oxidization apparatus is being stabilized, wherein the density of the ozone is 100 to 200 g/N m³.

16. The method as set forth in claim 11, wherein the radical oxidization apparatus is ramped up at the rate of 50 to 100° C./min with the pressure being set to 50 torr to atmospheric pressure.

17. The method as set forth in claim 11, wherein the radical oxidization process is performed using O₂ and H₂ gases at a temperature of 750 to 950° C. and a pressure of no more than 3 torr.

18. The method as set forth in claim 17, wherein the gases O₂ and H₂ have the ratio of 9:1 to 6:4 and are introduced so that a total flow rate is 1 to 10 slm.

19. The method as set forth in claim 11, wherein the first anneal process employing the NO gas is performed at a temperature of 750 to 1000° C. at the atmospheric pressure for about 5 to 60 minutes.

20. The method as set forth in claim 11, wherein the first anneal process employing the NO gas is performed using a mixed gas including NO and N₂ at a pressure of 10 to 750 torr for about 5 to 60 minutes.

21. The method as set forth in claim 11, wherein the second anneal process employing the mixed gas including O₂ and N₂ is performed by introducing a total flow rate of about 1 to 20 slm while maintaining the ratio of O₂ and N₂ to 1:20 to 5:5 for about 5 to 60 minutes.

22. The method as set forth in claim 21, wherein, the oxide film has a nitrogen concentration of 1 to 5 atomic %.
